(19) United States
(12) Patent Application Publication
(10) Pub. No.: US 2004/0034451 A1
(43) Pub. Date: Feb. 19, 2004

(54) Frequency shift key demodulator employing a teager operator and a method of operation thereof

(75) Inventors: Poovanpilli G. Madhavan, Harleysville, PA (US); Peter J. Goidas, Lansdale, PA (US); Frederick R. Giordiano, Coopersburg, PA (US)

Correspondence Address: HITT GAINES P.C., P.O. BOX 832570, RICHARDSON, TX, 75083, US

(73) Assignee: Agere Systems Inc., Allentown, PA

(21) Appl. No.: 10/164,941

(22) Filed: Jun. 6, 2002

(51) Int. Cl. H03D 3/00

(52) U.S. Cl. 700/300; 329/300

(57) ABSTRACT

A demodulator and demodulating system for use with a frequency shift key signal, and method of operation thereof. In one embodiment, the demodulator includes a receptor that is conf igured to receive a frequency shift key signal, and a discriminator coupled to the receptor that is conf igured to demodulate the frequency shift key signal by employing a Teager operator.

### TECHNICAL FIELD OF THE INVENTION

The present invention is directed, in general, to demodulation systems and, more specifically, to a system and method of demodulating a frequency shift key signal using a Teager operator.

### BACKGROUND OF THE INVENTION

Electrical signals containing time-varying information may be conveyed wirelessly from one point to another by modulating the signals onto a radio frequency carrier signal. Common processes of modulation may alter the amplitude, frequency or phase of the carrier signal wherein the level of modulation to the carrier signal determines the degree of variation in at least one of the parameters. A modulated signal may undergo undesired alterations during transmission typically through diminished signal strength that reduces its signal to noise characteristics. This may measurably increase the difficulty of demodulating the carrier to reliably recover the modulated signal. Therefore, the effects of noise or other distortions should be accommodated during the demodulation process to effectively recover the modulated information.

With the increasing use of computers and other digital electronic circuitry, the transmission of digital data and digital signal information has become extremely important. One digital data transmission format which has been utilized is frequency shift key transmission. A frequency shift key signal is created by modulating a reference or carrier signal proportional to the data to be transmitted. The transmitted signal then has frequencies which are either greater than or less than the frequency of the reference signal. The two frequencies of the transmitted frequency shift key signal may therefore be used to represent a modulating signal that contains both a logical one and a logical zero. A frequency shift key receiver may then receive and demodulate the transmitted frequency shift key signal to produce a serial data stream.

Presently, there are several demodulation techniques for a frequency shift key signal. Essentially, each frequency shift key demodulator detects a logical one or a logical zero from the modulated radio frequency signal. Several of the frequency shift key demodulators, for example, determine the logical one or the logical zero after mixing down the modulated signal to a baseband frequency. In order to accurately demodulate the signal, however, existing frequency shift key demodulators require several components and computational steps. When the modulated signal has a low signal to noise ratio, then extensive computations are typically required to obtain a clear demodulated signal.

Accordingly, what is needed in the art is a more effective way to demodulate a frequency shift key signal to provide a more reliable reproduction of the modulated information especially under adverse signal to noise conditions.

### SUMMARY OF THE INVENTION

To address the above-discussed deficiencies of the prior art, the present invention provides a demodulator for use with a frequency shift key signal. In one embodiment, the demodulator includes a receptor that is configured to receive a frequency shift key signal, and a discriminator coupled to the receptor that is configured to demodulate the frequency shift key signal by employing a Teager operator.

In another aspect, the present invention provides a method of demodulating a frequency shift key signal that includes receiving the frequency shift key signal, and discriminating the frequency shift key signal by employing a Teager operator. The method further includes providing a demodulated signal.

In yet another aspect, the present invention provides a demodulation system that includes an input circuit that receives a modulated frequency shift key signal, and an output circuit that provides a demodulated signal. The demodulation system also includes a frequency shift key demodulator coupled between the input circuit and the output circuit. The frequency shift key demodulator includes a receptor that receives the frequency shift key signal, and a discriminator coupled to the receptor that demodulates the frequency shift key signal by employing a Teager operator.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIGS. 1A, 1B, 1C and 1D illustrate system diagrams of embodiments of demodulation systems constructed in accordance with the principles of the present invention;

FIG. 2 illustrates a block diagram of an embodiment of a demodulator constructed in accordance with the principles of the present invention;

FIGS. 3A, 3B, 3C and 3D illustrate a collection of waveforms showing embodiments of a representation of a digital modulation signal, a corresponding modulated frequency shift key signal, a corresponding demodulated signal using a basic Teager operator and a corresponding demodulated signal using a generalized Teager operator, respectively, that are constructed in accordance with the principles of the present invention; and

FIG. 4 illustrates a flow diagram of an embodiment of a method of demodulating a frequency shift key signal constructed in accordance with the principles of the present invention.

### DETAILED DESCRIPTION

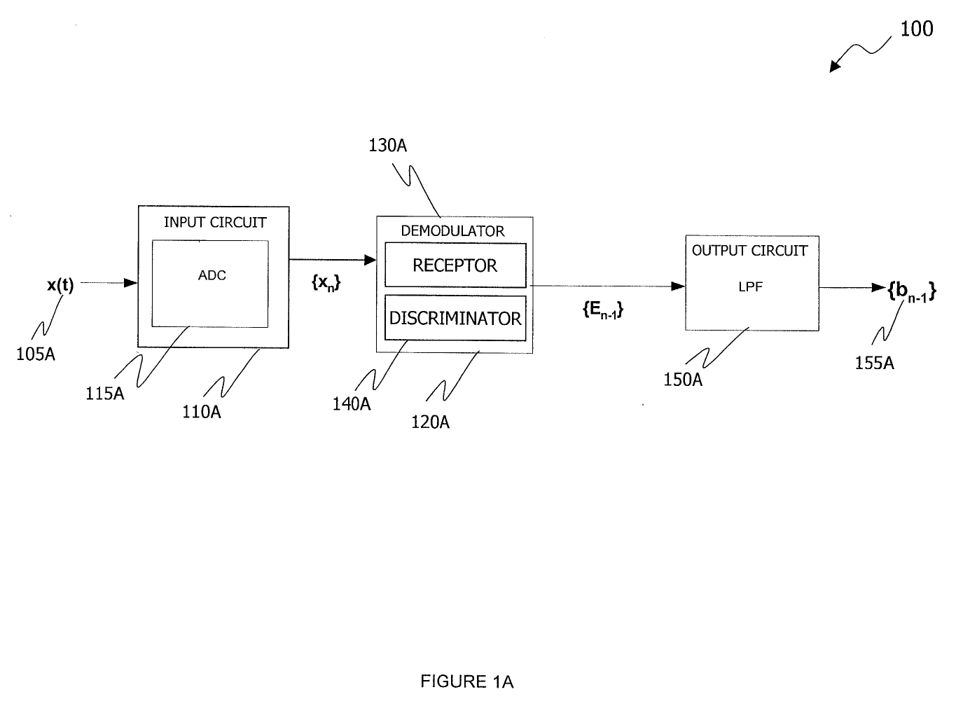

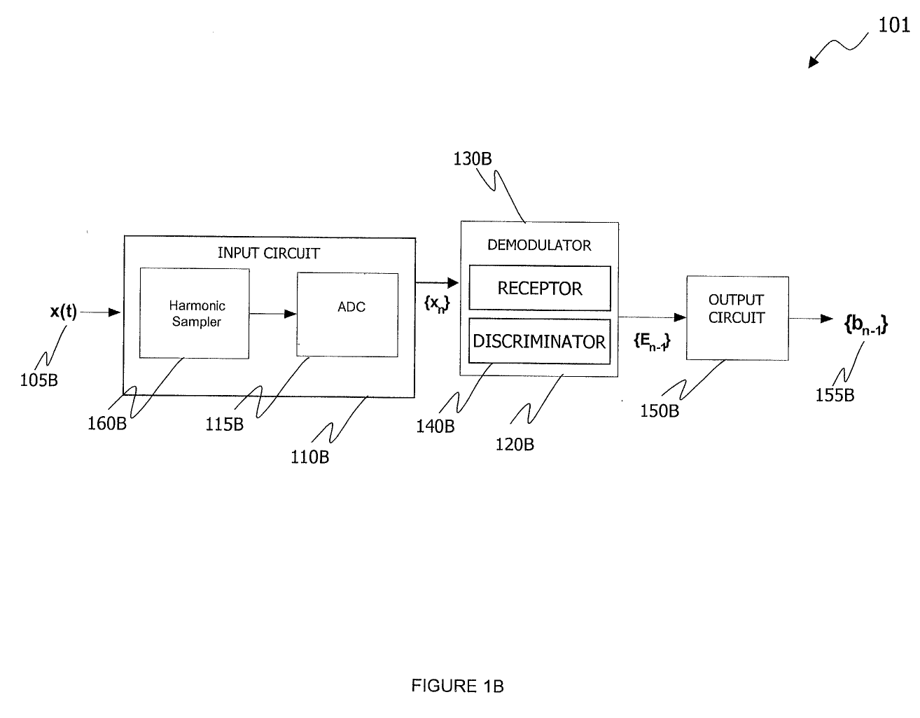

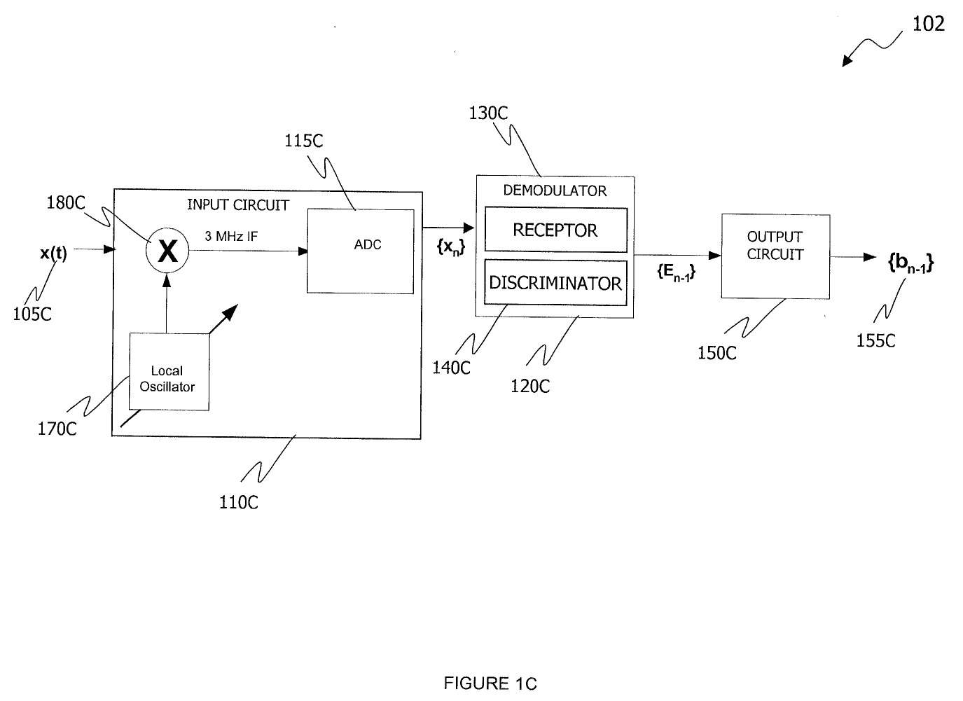

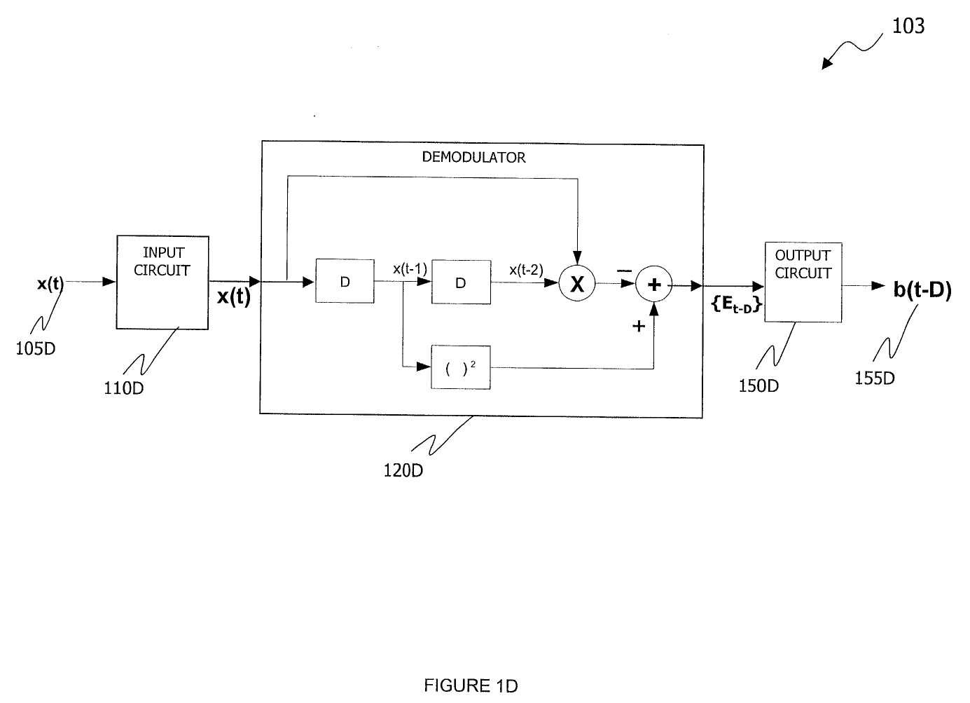

Referring initially to FIG. 1A, illustrated is a system diagram of an embodiment of a demodulation system, generally designated 100, constructed in accordance with the principles of the present invention. The demodulation system 100 includes an input circuit 110A, a demodulator 120A and an output circuit 150A. The input circuit 110A receives a modulated frequency shift key signal 105A, and the output circuit 150A provides a demodulated signal 155A. The demodulator 120A includes a receptor 130A coupled to a discriminator 140A.

In the illustrated embodiment, the input circuit 110A, employs a conventional analog to digital converter 115A. The analog to digital converter 115A is configured to convert an analog signal to a digital signal that represents equivalent information. The analog to digital conversion is an electronic process in which a continuously variable signal (analog) is changed, essentially without altering its content, into a multi-level (digital) signal. In one embodiment, the analog to digital converter 115A may operate at a frequency up to 10 GHz.

As in the illustrated embodiment, the modulated frequency shift key signal 105A is designated by a time varying representation xₜ. As shown in FIG. 1, the analog to digital converter 115A receives the modulated frequency shift key signal 105A and converts it into a digital signal xₙ. In other embodiments, the input circuit 110A may employ other circuits or components to receive and modify the modulated frequency shift key signal 105A. For examples, see discussions associated with FIGS. 1B and 1C below.

As mentioned above, the demodulator 120A includes the receptor 130A coupled to the discriminator 140A. The receptor 130A is configured to receive the modulated frequency shift key signal 105A from the input circuit 110A. In some embodiments, the receptor 130A may be employed embodied in a digital signal processor. In other embodiments, the receptor 130A may be employed embodied in analog components. In the illustrated embodiment, the receptor 130A is configured to receive a digital signal converted from the modulated frequency shift key signal 105A. In another embodiment, the receptor 130A may be configured to directly receive a continuous signal. For example, the receptor 130A may be configured to directly receive the modulated frequency shift key signal 105A.

The discriminator 140A receives the modulated frequency shift key signal 105A from the receptor 130A. The discriminator 140A is configured to demodulate the modulated frequency shift key signal 105A and provide an unfiltered demodulated signal (designated by an energy representation Eₙ₋₁) , by employing a Teager operator. In one embodiment, the Teager operator may be a basic Teager operator. In another embodiment, the Teager operator may be a generalized Teager operator. The basic and generalized Teager operators will be discussed below in more detail with respect to FIG. 2.

In FIG. 1A, the output circuit 150A is a low pass filter (designated by LPF in FIG. 1A). The low pass filter is a conventional low pass filter that reduces higher frequency noise from the demodulated signal to produce a clearer distinction between logical ones and logical zeros. One skilled in the art will understand the output circuit 150A may include other components in addition to or instead of the low pass filter to assist in producing an accurate demodulated signal 155A. In the illustrated embodiment, the demodulated signal 155A is designated by a digital representation bₙ₋₁.

Turning now to FIG. 1B, illustrated is a system diagram of an embodiment of a demodulation system, generally designated 101, constructed in accordance with the principles of the present invention. The demodulation system 101 includes an input circuit 110B, a demodulator 120B and an output circuit 150B. In general, the demodulation system 101 corresponds to the demodulation system 100 except for the input circuit 110B. In FIG. 1B, the input circuit 110B includes a harmonic sampler 160B and an analog to digital converter 115B. The input circuit 110B receives a modulated frequency shift key signal 105B, and the output circuit 150B provides a demodulated signal 155B. The demodulator 120B includes a receptor 130B coupled to a discriminator 140B.

The harmonic sampler 160B is a conventional harmonic sampler that is configured to convert a signal to a baseband by taking harmonic samples. For example, the modulated frequency shift key signal 105B may be a Bluetooth signal which is in the frequency range of 2.4 GHz. The harmonic sampler 160B may receive the Bluetooth signal and convert it down to a baseband of a lower frequency that can be processed by an existing analog to digital converter.

The analog to digital converter 115B is a conventional analog to digital converter as described above with respect to FIG. 1A. In the illustrated embodiment of FIG. 1B, the analog to digital converter 115B may operate at a frequency up to 600 KHz. One skilled in the art will understand that the analog to digital converter 115B may operate at other frequencies.

Turning now to FIG. 1C, illustrated is a system diagram of an embodiment of a demodulation system, generally designated 102, constructed in accordance with the principles of the present invention. The demodulation system 102 includes an input circuit 110C, a demodulator 120C and an output circuit 150C. The input circuit 110C receives a modulated frequency shift key signal 105C, and the output circuit 150C provides a demodulated signal 155C. The demodulator 120C includes a receptor 130C coupled to a discriminator 140C. In general, the demodulation system 102 corresponds to the demodulation system 100 except for the input circuit 110C. In FIG. 1C, the input circuit 110C includes an oscillator 170C, a mixer 180C and an analog to digital converter 115C. The input circuit 110C receives a modulated frequency shift key signal 105C, and the output circuit 150C provides a demodulated signal 155C. The demodulator 120C includes a receptor 130C coupled to a discriminator 140C.

In FIG. 1C, the oscillator 170C and the mixer 180C are a conventional oscillator and mixer that receive the modulated frequency shift key signal 105C and mix it down to an intermediate frequency that allows conversion by the analog to digital converter 115C. In the illustrated embodiment, the oscillator 170C and the mixer 180C may mix down the modulated frequency shift key signal 105C to an intermediate frequency (IF) as low as 3 Mhz to allow processing by the analog to digital converter 115C. In this embodiment, the analog to digital converter 115C may operate up to a frequency of 12 MHz.

Turning now to FIG. 1D, illustrated is a system diagram of an embodiment of a demodulation system, generally designated 103, constructed in accordance with the principles of the present invention. The demodulation system 103 includes an input circuit 110D, a demodulator 120D and an output circuit 150D. As discussed above with respect to FIGS. 1A, 1B and 1C, the input circuit 110D receives a modulated frequency shift key signal 105D, and the output circuit 150D provides a demodulated signal 155D. In the demodulation system 103, the demodulated signal 155D, however, is a delayed time varying signal b_{t-D}, and the output of the demodulator 120D is designated by an energy representation E_{t-D}, of the modulated frequency shift key signal 105D. Otherwise, the demodulation system 103 corresponds to the demodulation system 100, 101 and 102, respectively, except for the demodulator 120D.

In FIGS. 1A, 1B and 1C, the demodulators 120A, 120B and 120C, respectively, may be employed in a conventional digital signal processor. As illustrated in FIG. 1D the demodulator 120D may also be employed using analog components. As an alternative to the digital signal processor methodology, common analog mixers and other components may be used to discriminate the frequencies of the modulated frequency shift key signal 105D. Analog embodiments of a demodulator may permit constructing the demodulator 120D using readily available components. This may provide a simple way of demodulating the modulated frequency shift key signal 105D when it is, for example, a Bluetooth signal.

Turning now to FIG. 2, illustrated is a block diagram of an embodiment of a demodulator, generally designated 200, constructed in accordance with the principles of the present invention. The demodulator 200 includes an input 210, an output 220, a receptor 230 and a discriminator 240. The input 210 is designated by a digital representation xₙ of a time varying representation xₜ of a modulated signal. The output 220 is designated by an energy representation Eₙ₋₁ of the input 210.

In the illustrated embodiment, the receptor 230 and the discriminator 240 are employed within a conventional digital signal processor. In other embodiments, the receptor may employ analog components. The receptor 230, coupled to the discriminator 240, may receive the digital conversion of a frequency shift key signal. In some embodiments, the frequency shift key signal may be a Bluetooth signal.

The discriminator 240 is configured to demodulate the frequency shift key signal by employing a Teager operator. As discussed above, the Teager operator may be a basic Teager operator or a generalized Teager operator. As described in “On a Simple Algorithm to Calculate 'Energy of a Signal,” by James F. Kaiser, PROC. ICASSP, Vol. S7.3, pps. 381-384, 1990, which is incorporated herein by reference, the basic Teager operator is an algorithm introduced to calculate the “energy” of a signal. The algorithm, given below, calculates a value E(n−1) and has been shown to be related to “energy” of the signal being analyzed x(n−1).

E(n−1)=x²(n−1)−x(n−2)x(n)

As described in “On Amplitude and Frequency Demodulation Using Energy Operators,” by Petros Maragos, et al., IEEE Transactions On Signal Processing, Vol. 41, No. 4, page 1532, April 1993, which is incorporated herein by reference, the basic Teager operator may be used to demodulate a modulated signal by estimating the energy of the modulated signal. Using the basic Teager operator, a frequency shift key signal may also be demodulated by a few operations consisting of two multiplications and one addition per sample.

In another embodiment, the basic Teager operator may be generalized to form yet another estimate for demodulating a frequency shift key signal. As with the basic Teager operator, the generalized Teager operator may be used to demodulate a modulated signal by estimating the energy of the modulated signal. The generalized Teager operator is a function of an estimate of the energy distribution of the signal and an inverse Fourier transform of the energy distribution of the signal. While better suited for some applications in demodulating a modulated signal, the generalized Teager operator may require more computations than the basic Teager operator. For an example of using both the basic and generalized Teager operator, see U.S. Pat. No. 6,004,017 entitled “Teager-Based Method and System for Predicting Limit Cycle Oscillations and Control Method and System Utilizing Same,” to Madhavan, issued on Dec. 21, 1999, which is incorporated herein by reference.

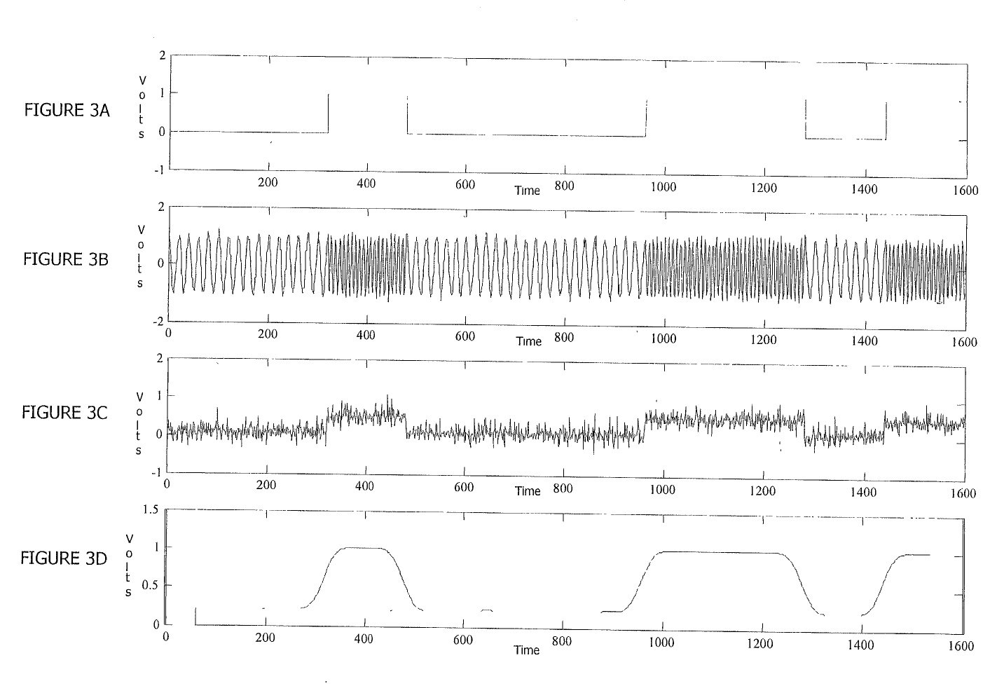

Turning now to FIGS. 3A, 3B, 3C and 3D, illustrated are a collection of waveforms showing embodiments of a representation of a digital modulation signal, a corresponding modulated frequency shift key signal, a corresponding demodulated signal using a basic Teager operator and a corresponding demodulated signal using a generalized Teager operator that are constructed in accordance with the principles of the present invention.

Regarding FIG. 3A, illustrated is the digital modulation signal representing data to be transmitted using a radio frequency signal. The source of the data may be from video, audio or a digital device such as a computer. Using a conventional frequency shift key modulator, the radio frequency carrier is modulated and transmitted.

Regarding FIG. 3B, illustrated is the corresponding modulated frequency shift key signal that has been transmitted. The modulated frequency shift key signal of FIG. 3B includes noise from the environment obtained during transmission.

Regarding FIG. 3C, illustrated is the corresponding demodulated signal using a basic Teager operator representing a demodulated waveform of the modulated frequency shift key signal in FIG. 3B. Like the modulated frequency shift key signal in FIG. 3B, the corresponding demodulated signal using a basic Teager operator of FIG. 3C includes noise from the environment. In one embodiment, the corresponding demodulated signal using a basic Teager operator may be a Bluetooth signal. In this embodiment, the carrier signal would be about 2.4 GHz, and a logical one and a logical zero would be represented by 2450.15 MHz and 2449.85 MHz, respectively.

Regarding FIG. 3D, illustrated is the corresponding demodulated signal using a generalized Teager operator of the modulated frequency shift key signal in FIG. 3B. By using the additional computations of the generalized Teager operator as compared to the basic Teager operator, the demodulation yields a waveform with an increased distinction between a logical one and a logical zero of the modulated frequency shift key signal. Using the generalized Teager operator typically results in a higher signal to noise ratio and an increase in the quality of the received demodulated signal.

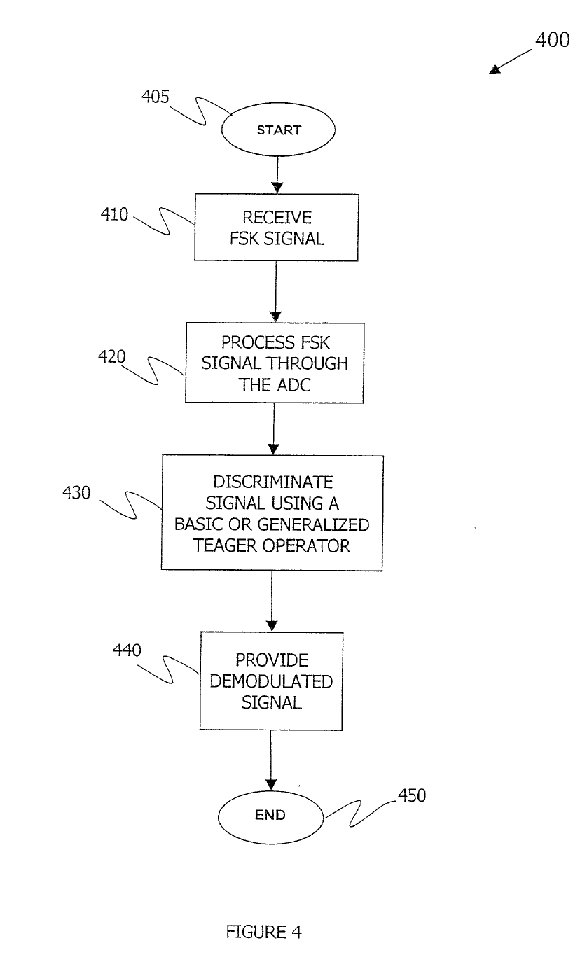

Turning now to FIG. 4, illustrated is a flow diagram of an embodiment of a method, generally designated 400, of demodulating a modulated frequency shift key signal in accordance with the principles of the present invention. The method 400 starts in a step 405 with an intent to demodulate a frequency shift key signal.

Following the step 405, a demodulator receives a modulated frequency shift key signal in a step 410. The modulated frequency shift key signal may be a Bluetooth signal. In some embodiments, the demodulator may receive the modulated frequency shift key signal within a digital signal processor. In other embodiments, the demodulator may receive the modulated frequency shift key signal by employing analog components.

After receiving the modulated frequency shift key signal, the demodulator processes the modulated frequency shift key signal through the analog to digital converter in a step 420. The analog to digital converter may be a conventional analog to digital converter that converts an analog signal to a digital signal that represents equivalent information. In one embodiment, the analog to digital converter may operate at a frequency up to 10 GHz.

After processing through the analog to digital converter, the demodulator discriminates the digital conversion of the modulated frequency shift key signal using a basic Teager operator or a generalized Teager operator in a step 430. The type of Teager operator used may be determined by the embodiment of the demodulator. In some embodiments, the demodulator may discriminate within a digital signal processor. In other embodiments, the demodulator may discriminate the modulated frequency shift key signal by employing analog components and not employing an analog to digital converter.

Using the basic Teager operator, the demodulator would typically discriminate the modulated frequencies of the shift key signal using two multiplications and a subtraction of each sampling of the signal. In some embodiments, the demodulator may discriminate the modulated frequency shift key signal using a generalized Teager operator. A demodulator using the generalized Teager operator may allow a user to choose a more expensive demodulator which provides very high-fidelity demodulation, for example see FIG. 3D, but requires more computations than the basic Teager operator.

After discriminating using a either a basic Teager operator or a generalized Teager operator, the demodulator provides an unfiltered demodulated signal in a step 440. In one embodiment, the unfiltered demodulated signal may be provided to a low pass filter. Finally, demodulating a modulated frequency shift key signal ends at a step 450.

Although the present invention has been described in detail, those skilled in the art should understand that they can make various changes, substitutions and alterations herein without departing from the spirit and scope of the invention in its broadest form.

What is claimed is:

1. A demodulator for use with a frequency shift key signal, comprising:
a receptor configured to receive said frequency shift key signal; and
a discriminator coupled to said receptor configured to demodulate said frequency shift key signal by employing a Teager operator.

2. The demodulator as recited in claim 1 wherein said frequency shift key signal represents a Bluetooth signal.

3. The demodulator as recited in claim 1 wherein said receptor and said discriminator are embodied in a digital signal processor.

4. The demodulator as recited in claim 1 wherein said receptor and said discriminator employ analog components.

5. The demodulator as recited in claim 1 wherein said Teager operator is a basic Teager operator.

6. The demodulator as recited in claim 1 wherein said Teager operator is a generalized Teager operator.

7. A method of demodulating a modulated frequency shift key signal, comprising:
receiving said frequency shift key signal;
discriminating said frequency shift key signal by employing a Teager operator; and
providing an unfiltered demodulated signal.

8. The method as recited in claim 7 wherein said frequency shift key signal represents a Bluetooth signal.

9. The method as recited in claim 7 wherein said receiving and said discriminating are performed within a digital signal processor.

10. The method as recited in claim 7 wherein said receiving and said discriminating are performed by employing analog components.

11. The method as recited in claim 7 wherein said Teager operator is a basic Teager operator.

12. The method as recited in claim 7 wherein said Teager operator is a generalized Teager operator.

13. A demodulation system, comprising:
an input circuit that receives a modulated frequency shift key signal;
an output circuit that provides a demodulated signal; and
a frequency shift key demodulator coupled between said input circuit and said output circuit, including:
a receptor that receives said frequency shift key signal, and
a discriminator coupled to said receptor that demodulates said frequency shift key signal by employing a Teager operator.

14. The demodulation system as recited in claim 13 wherein said input circuit employs an analog to digital converter.

15. The demodulation system as recited in claim 14 wherein said frequency shift key signal represents a Bluetooth signal.

16. The demodulation system as recited in claim 14 wherein said receptor and said discriminator are embodied in a digital signal processor.

17. The demodulation system as recited in claim 13 wherein said rec eptor and said discriminator employ analog components.

18. The demodulation system as recited in claim 13 wherein said Teager operator is a basic Teager operator.

19. The demodulation system as recited in claim 13 wherein said Teager operator is a generalized Teager operator.

20. The demodulation system as recited in claim 13 wherein said input circuit employs a harmonic sampler.

21. The demodulation system as recited in claim 13 wherein said input circuit employs a mixer.
